(19) United States
(12) Patent Application Publication
(10) Pub. No.: US 2011/0012090 A1
(43) Pub. Date: Jan. 20, 2011

(54) SILICON-GERMANIUM NANOWIRE STRUCTURE AND A METHOD OF FORMING THE SAME

(75) Inventors: Navab Singh, Singapore (SG); Jiang Yu, Singapore (SG); Guo Qiang Patrick Lo, Singapore (SG)

Correspondence Address: Altera Law Group, LLC, 220 S 6 St Suite 1700, Minneapolis, MN, 55402, US

(73) Assignee: AGENCY FOR SCIENCE, TECHNOLOGY AND RESEARCH, Singapore (SG)

(21) Appl. No.: 12/746,347

(22) PCT Filed: Dec. 7, 2007
(86) PCT No.: PCT/SG2007/000422

§ 371 Date: Sep. 14, 2010

(51) Int. Cl. H01L 29/775; H01L 21/64; H01L 21/335; H01L 21/04; H01L 29/737

(52) U.S. Cl. 257/24; 438/142; 438/149; 257/12; 257/E29.245

(57) ABSTRACT

A silicon-germanium nanowire structure arranged on a support substrate is disclosed, The silicon-germanium nanowire structure includes at least one germanium-containing supporting portion arranged on the support substrate, at least one germanium-containing nanowire disposed above the support substrate and arranged adjacent the at least one germanium-containing supporting portion, wherein germanium concentration of the at least one germanium-containing nanowire is higher than the at least one germanium-containing supporting portion. A transistor comprising the silicon-germanium nanowire structure arranged on a support substrate is also provided. A method of forming a silicon-germanium nanowire structure arranged on a support substrate and a method of forming a transistor comprising forming the silicon-germanium nanowire structure arranged on a support substrate are also disclosed.

### FIELD OF THE INVENTION

Embodiments of the invention relate to field of nanowire structures. By way of example, embodiments of the invention relate to a silicon-germanium (SiGe) nanowire structure arranged on a support substrate and a method of forming the same.

### BACKGROUND OF THE INVENTION

Nanowire transistors with gate fully surrounding the channel body have become promising device architectures to take the scaling to end-of-the-CMOS technology roadmap. One example involves fully complementary metal oxide semiconductor (CMOS) compatible Silicon-nanowire (SiNW) Gate-All-Around (GAA) n-channel metal-oxide-semiconductor field effect transistor (NMOSFET) and p-channel metal-oxide-semiconductor field effect transistor (PMOSFET) fabricated with nanowire channel in different crystal orientations and characterized at various temperatures down to 5K. SiNW width is controlled in 1 nm steps and varied from 3 to 6 nm. Devices show high drive current (2.4 mA/μm for NMOSFET. 1.3 mA/μm for PMOSFET), excellent gate control, and reduced sensitivity to temperature. Strong evidences of carrier confinement are noticed in terms of Id-Vg oscillations and shift in threshold voltage with SiNW diameter. Orientation impact has been investigated as well.

Another example involves both GAA and bulk devices and are shown operational on the same chip. GAA transistors have been realized with a minimal gate length of 50 nm, with a conduction channel thickness of 20 nm, an oxide thickness of 20 A, and with an in-situ doped amorphous-Si as gate material. These transistors show a perfect immunity to short-channel effect (SCE)/Drain Induced Barrier Lowering (DIBL) even without pockets implants. The bulk devices measured on the same chip were functional (allowing drive current of more than 600 pNpm on 90 nm devices) but have shown large SCE/DIBL up to 600 mV and up to 1000 mV on 90 nm and 50 nm devices, respectively.

Yet another example involves a nanowire FinFET structure developed for CMOS device scaling into the sub 10 nm regime. Accumulation mode P-FET and inversion mode N-FET with 5 nm and 10 nm physical gate lengths, respectively, are fabricated. N-FET gate delay (CV/I) of 0.22 ps and P-FET gate delay of 0.48 ps with excellent subthreshold characteristics are achieved, both with very low off leakage current less than 10 nA/p.m. Nanowire FinFET device operation is also explored using 3-D full quantum mechanical simulation.

Nanowires are fabricated or synthesized by either top-down or bottom-up approaches. As there have been issues of controllability, placement and poor compatibility with standard Si-CMOS fabrication in relation to the bottom-up approach of fabrication, the top-down approach has taken the lead as a potential technology solution for future Si-CMOS.

An example of a top-down approach involves GAA Twin-Si-nanowire MOSFET (TSNWFET) with 15 nm gate length and 4 nm radius nanowires. The GAA TSNWFET demonstrated shows excellent short channel immunity. P-TSNWFET shows high driving current of 1.94 mA/μm while n-TSNWFET shows on-current of 1.44 mA/μm. Merits of TSNWFET and performance enhancement of p-TSNWFET have been explored using 3-D and quantum simulation.

Another example of a top-down approach involves a method for realizing arrays of vertically stacked laterally spread out nanowires using a fully Si-CMOS compatible process. The GAA MOSFET devices using these nanowire arrays show excellent performance in terms of near ideal sub-threshold slope (<70 mV/dec), high Ion/Ioff ratio (˜107), and low leakage current. Vertical stacking economizes on silicon estate and improves the on-state IDSAT at the same time. Both n- and p-FET devices have been demonstrated.

In addition to nanowire transistors, heterostructure transistors have also been proposed for high-speed CMOS circuits. One example involves a new generation of high-speed heterostructure devices compatible with a modified Modulation-Doped Field Effect Transistor (MODFET). These devices include a modified MODFET with a buried p-channel, a variable threshold voltage MODFET, a lateral n-p-n bipolar transistor, and a three-terminal planar photodetector. These devices can be integrated together and with an optical waveguide. The MODFET has high speed, high collection efficiency, and it may operate in either p-i-n mode with low noise or the avalanche mode with high gain. The gate terminal allows modulation of the photodetector output.

Further, based on the principle of high injection velocity heterojunction bipolar transistor (HBT), a planar MOSFET structure with a heterojunction source structure has been demonstrated. It involves a source-heterojunction-MOS-transistor (SHOT), which is a novel high-speed MOSFET with relaxed-SiGe/strained-Si heterojunction source structures for quasi-ballistic or full-ballistic transistors. Using the band-offset energy at the source SiGe/strained-Si heterojunction, high velocity electrons can be injected into the strained-Si channel from the SiGe source region. The publication experimentally demonstrated that the transconductance is enhanced in SHOT for high applied drain voltage, compared to that of strained- and conventional silicon-on-insulator (SOI) MOSFETs. The publication also shows that the transconductance enhancement in SHOT depends on both the gate drive and the drain bias.

However, there is still a need for a transistor with better channel mobility and higher current.

### SUMMARY OF THE INVENTION

In one embodiment of the invention, a silicon-germanium nanowire structure arranged on a support substrate is provided. The method includes at least one germanium-containing supporting portion arranged on the support substrate, at least one germanium-containing nanowire disposed above the support substrate and arranged adjacent the at least one germanium-containing supporting portion, wherein germanium concentration of the at least one germanium-containing nanowire is higher than the at least one germanium-containing supporting portion.

In another embodiment of the invention, a transistor comprising the silicon-germanium nanowire structure arranged on a support substrate is provided. The transistor further includes a tunneling layer around the at least one germanium-containing nanowire and a gate region positioned over the tunneling layer.

In another embodiment of the invention, a method of forming a silicon-germanium nanowire structure arranged on a support substrate is disclosed. The method includes forming at least one germanium-containing supporting portion on the support substrate, forming at least one germanium-containing nanowire above the support substrate and adjacent the at least one germanium-containing supporting portion, wherein germanium concentration of the at least one germanium-containing nanowire is higher than the at least one germanium-containing supporting portion.

In a further embodiment of the invention, a method of forming a transistor comprising forming the silicon-germanium nanowire structure arranged on a support substrate is disclosed. The method further includes forming a tunneling layer around the at least one germanium-containing nanowire and forming a gate region positioned over the tunneling layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a cross-sectional view of a silicon-germanium nanowire (SGNW) transistor in accordance with an embodiment of the invention;

FIG. 2 shows a band diagram corresponding to a cross-sectional view of a SGNW transistor in accordance with an embodiment of the invention;

FIG. 3A to FIG. 3H show a process flow of a method of forming a SGNW transistor in accordance with an embodiment of the invention;

FIG. 4A show a cross-sectional view along plane AA′ of the SGNW transistor in FIG. 3E after fin patterning and before second Ge condensation in accordance with an embodiment of the present invention; FIG. 4B show a cross-sectional view along plane AA′ of the SGNW transistor in FIG. 3E after fin patterning and after second Ge condensation in accordance with an embodiment of the present invention;

FIG. 5A and FIG. 5B show cross-sectional views along planes AA′ and BB′ of the SGNW transistor in FIG. 3F in accordance with an embodiment of the invention;

FIG. 6A and FIG. 6B show respective cross-sectional views along plane AA′ of the SGNW transistor in FIG. 3G with the resultant structure being a MOSFET or a Silicon-Oxide-Nitride-Oxide-Silicon (SONOS) memory device in accordance with an embodiment of the invention;

FIG. 7 shows a flow chart of a method of forming a SGNW transistor in accordance with an embodiment of the invention;

FIG. 8A shows a scanning electron microscopy (SEM) image of a SGNW structure taken after a second Ge condensation process in accordance with an embodiment of the invention; FIG. 8B shows a SEM image of a SGNW structure after gate pattern transfer in accordance with an embodiment of the invention; FIG. 8C shows a cross-sectional High Resolution Transmission Electron Microscopy (HRTEM) image of a SGNW in accordance with an embodiment of the invention;

FIG. 9A shows a SEM image of a SGNW structure after nanowire release in accordance with an embodiment of the invention; FIG. 9B shows a SEM image of a SGNW structure after nanowire release taken with about 45 degree rotation in accordance with an embodiment of the invention;

FIG. 10A shows a TEM image of a SGNW GAA FET with HfO₂/TaN gate in accordance with an embodiment of the invention; FIG. 10B shows a magnified image of a near-circular SGNW in accordance with an embodiment of the invention; FIG. 10C shows a reciprocal space diffractogram showing a lattice structure inside the SGNW in accordance with an embodiment of the invention;

FIG. 11 shows a normalized I_{D} vs V_{D} characteristics plot of a SGNW PMOSFET and a Si_{0.7}Ge_{0.3} homo planar device with gate length (Lg) of approximately 350 nm in accordance with an embodiment of the invention;

FIG. 12 shows a transconductance (g_{M}) vs gate voltage (V_{G}) characteristic plot of a SGNW PMOSFET and a Si_{0.7}Ge_{0.3} homo planar device with Lg of approximately 350 nm in accordance with an embodiment of the invention;

FIG. 13 shows a drive current (I_{Dsat}) vs temperature characteristic plot of a SGNW PMOSFET and a Si_{0.7}Ge_{0.3} homo planar device with Lg of approximately 350 nm in accordance with an embodiment of the invention;

FIG. 14 shows a threshold voltage (V_{T}) vs temperature characteristics plot of a SGNW PMOSFET and a Si_{0.7}Ge_{0.3} homo planar device with Lg of approximately 350 nm in accordance with an embodiment of the invention;

FIG. 15 shows a I_{D} vs V_{G} characteristics plot of a SGNW PMOSFET with Lg of 500 nm in accordance with an embodiment of the invention;

FIG. 16 shows a I_{D} vs V_{D} characteristics plot of a SGNW PMOSFET with Lg of 500 nm in accordance with an embodiment of the invention;

FIG. 17 shows a g_{M} vs V_{G} characteristics plot of a SGNW PMOSFET with Lg of 500 nm in accordance with an embodiment of the invention;

FIG. 18 shows a resistance vs V_{G} characteristics plot of a SGNW PMOSFET at strong inversion with low V_{D} in accordance with an embodiment of the invention;

FIG. 19 shows a V_{T} vs temperature characteristics plot of SGNW PMOSFET with respective gate lengths of 350 nm, 400 nm and 500 nm in accordance with an embodiment of the invention;

FIG. 20 shows a linear g_{M} peak vs temperature characteristics plot of SGNW PMOSFET with respective gate lengths of 350 nm, 400 nm and 500 nm in accordance with an embodiment of the invention;

FIG. 21 shows a I_{ON} vs I_{OFF} characteristics plot of SGNW PMOSFET with respective radii of 6 nm and 8 nm in accordance with an embodiment of the invention;

FIG. 22 shows a I_{D} vs V_{G} characteristics plot of a SGNW PMOSFET with <100> channel direction in accordance with an embodiment of the invention;

FIG. 23 shows a I_{D} vs V_{D} characteristics plot of a SGNW PMOSFET with <100> channel direction in accordance with an embodiment of the invention;

FIG. 24 shows a I_{D} vs V_{G} characteristics plot of a unpassivated SGNW NMOSFET in accordance with an embodiment of the invention;

FIG. 25 shows a I_{D} vs V_{D} characteristics plot of a unpassivated SGNW NMOSFET in accordance with an embodiment of the invention;

FIG. 26 shows a V_{OUT} vs V_{IN} characteristics plot of a CMOS inverter incorporating a SGNW structure in accordance with an embodiment of the invention;

### DESCRIPTION

Exemplary embodiments of a silicon-germanium nanowire structure on a support substrate, and a method of forming the same are described in details below with reference to the accompanying figures. In addition, the exemplary embodiments described below can be modified in various aspects without changing the essence of the invention.

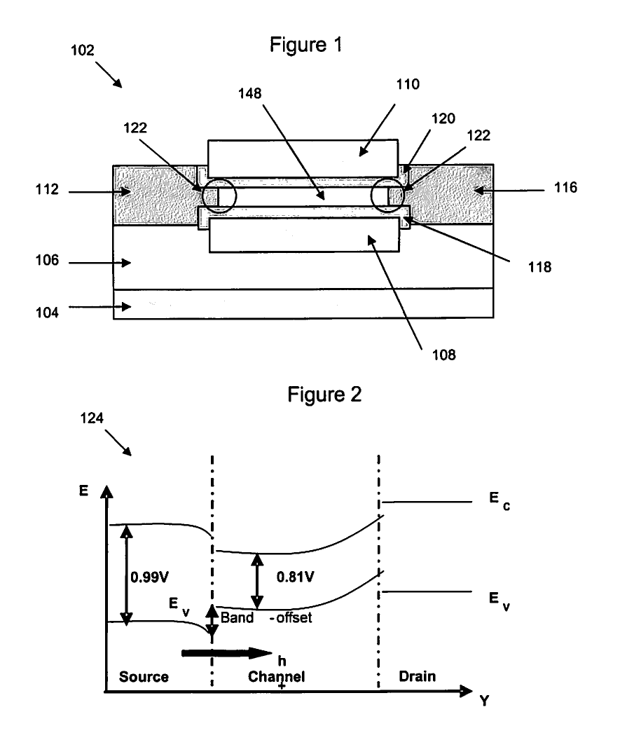

FIG. 1 shows a cross-sectional view of a SGNW transistor 102 in accordance with an embodiment of the invention. The SGNW transistor 102 includes a support substrate 104, a buried oxide (BOX) layer 106, a bottom gate electrode 108, a top gate electrode 110, a source region 112, a nanowire channel region 148 and a drain region 116. The bottom gate electrode 108 is separated from the source region 112, the nanowire channel region 148 and the drain region 116 by a bottom gate dielectric layer 118 and the top gate electrode 110 is separated from the source region 112, the nanowire channel region 148 and the drain region 116 by a top gate dielectric layer 120. The bottom gate electrode 108 and the top gate electrode 110 may be separate electrodes or may be a single electrode surrounding the nanowire channel region 148. Similarly the bottom gate dielectric layer 118 and the top gate dielectric layer 120 may be separate dielectric layers or a single dielectric layer surrounding the nanowire channel region 148.

The support substrate 104 may be formed from any suitable semiconductor materials including, but not limited to Si, sapphire, poly-silicon, silicon oxide (SiO₂) or silicon nitride (Si₃N₄). The BOX layer 106 is usually an insulating layer. The BOX layer 106 is typically silicon oxide (SiO₂) but may be formed from any suitable insulating materials including, but not limited to tetraethylorthosilicate (TEOS), silane (SiH₄), silicon nitride (Si₃N₄) or silicon carbide (SiC). The thickness of the BOX layer 106 may range from about 1 kA to about a few μm but is not so limited. The top 120 and bottom gate dielectric layer 118 can be any suitable dielectric, for example silicon nitride (Si₃N₄, SiNₓ), Magnesium Oxide (MgO) or Scandium Oxide (Sc₂O₃), typically SiO₂ but not so limited. The source region 112, the drain region 116 and the nanowire channel region 148 may be formed of SiGe. The bottom gate electrode 108 and the top gate electrode 110 may be Si, poly-silicon (poly-Si), amorphous silicon, metals such as tantalum nitride (TaN), titanium nitride (TiN), hafnium nitride (HfN), aluminum (Al) and tungsten (W) but not so limited.

The Ge concentration in the nanowire channel region 148 is higher than that in the source region 112 or in the drain region 116. The difference in Ge concentration results in the formation of a heterojunction 122 at the respective interface between the source region 112 and the nanowire channel region 148 and between the drain region 116 and the nanowire channel region 148. The Ge concentration in the nanowire channel region 148 is typically in the range of about 50% to 90%, preferably about 70%. The Ge concentration in the respective source region 112 or drain region 116 is typically about 10% to 50%, preferably about 30%. The higher the Ge concentration in the nanowire channel region 148, the higher the channel mobility. For a SiGe substrate, the higher the Ge content, the higher the carrier mobility for carrier inside such channel. This applies to both electrons and holes.

FIG. 2 shows a band diagram corresponding to a cross-sectional view of a SGNW transistor 102 in accordance with an embodiment of the invention. The band diagram 124 shows the respective valence band energy value (E_{V}) and conduction band energy value (E_{C}) of the source region 112, the SGNW channel region 148 and the drain region 116. From the difference in E_{V} and E_{C} between the source region 112 and the SGNW channel region 148 and between the SGNW channel region 148 and the drain region 116, it can be inferred that two respective heterojunctions 122 are formed. One of the heterojunction 122 is formed at the interface between the source region 112 and the SGNW channel region 148 and the other heterojunction 122 is formed at the interface between the drain region 116 and the SGNW channel region 148.

With higher Ge concentration in the SGNW channel region 148, the band gap of the SGNW channel region 148 decreases significantly as given by E_{g} (alloy)=x E_{g1}+(1−x) E_{g2}, with x being the Ge fraction in the SGNW channel region 148 and E_{g1}, E_{g2} being the band gaps of Ge and Si respectively. As an illustration, with about 30% Ge concentration in the respective source region 112 and drain region 116 and about 70% Ge concentration in the channel region 148, the band gap E_{g} or energy difference between the E_{C} and the E_{V} in the respective source region 112 and drain region 116 is about 0.99 electron volts (eV) and the band gap in the channel region 148 is about 0.81 eV without considering the strain effect in the SGNW channel 148. This results in a valence band offset ΔEv or energy difference between the valence band E_{V} values in the channel region 148 and the source region 112 of about 0.15 eV. Hole injection velocity may increase with a higher valence band offset ΔEv.

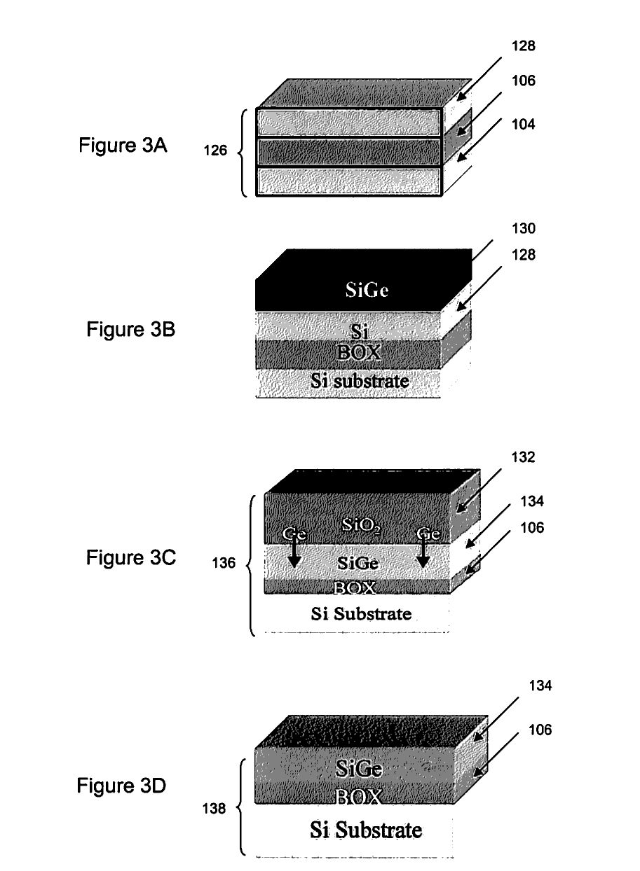

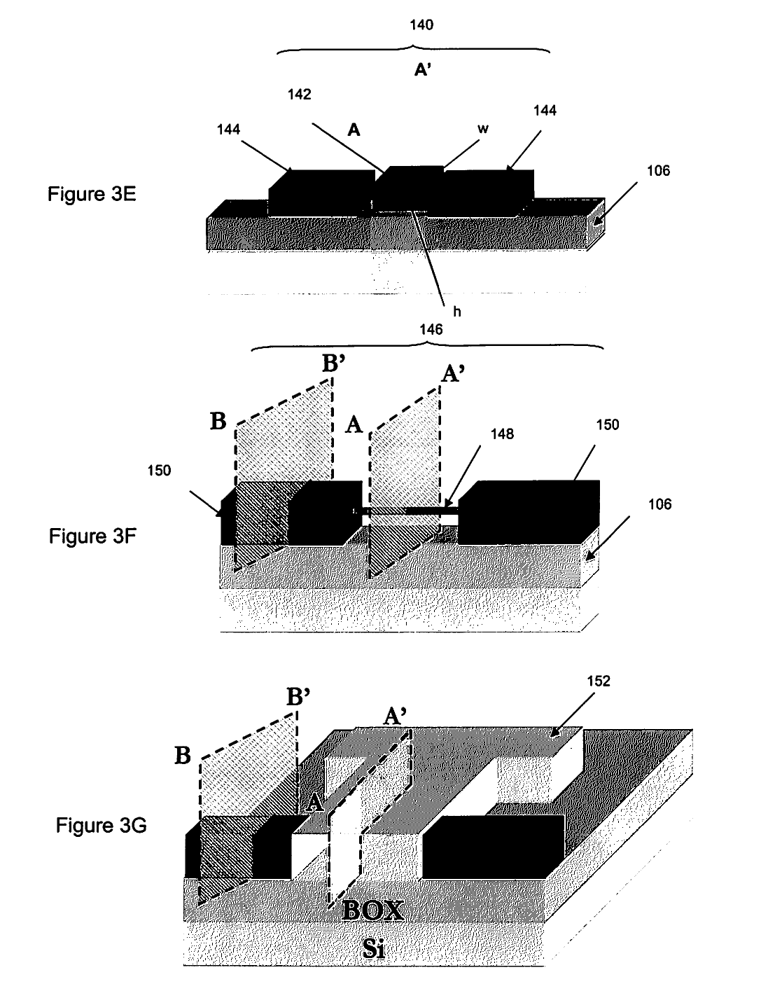

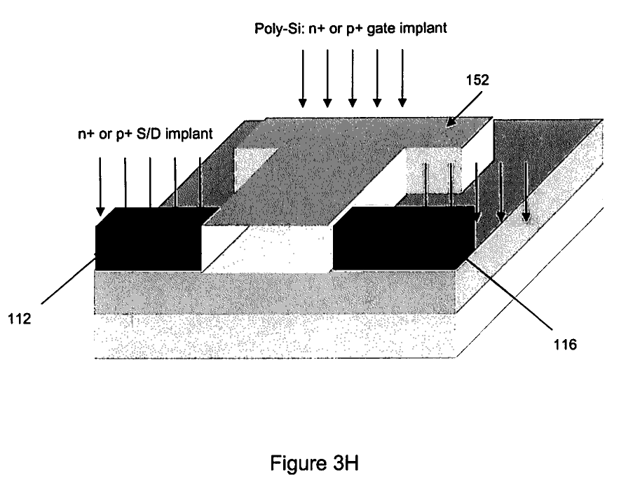

FIG. 3A to 3H show a process flow of a method of forming a SGNW transistor in accordance with an embodiment of the invention. The method starts with a starting substrate 126 in FIG. 3A. The starting substrate 126 can be a Silicon-On-Insulator (SOI) substrate, a bulk silicon substrate, or other relevant substrates depending on the application. The SOI substrate 126 is used as an illustration in FIG. 3A. The SOI substrate 126 includes a semiconductor device layer 128 separated vertically from a support substrate 104 by an insulating layer or a buried oxide (BOX) layer 106. The BOX layer 106 electrically isolates the semiconductor device layer 128 from the support substrate 104. The SOI substrate 126 may be fabricated by any standard techniques, such as wafer bonding or a separation by implantation of oxygen (SIMOX) technique.

In the illustrated embodiment of the invention in FIG. 3A, the semiconductor device layer 128 is typically Si but may be formed from any suitable semiconductor materials including, but not limited to poly-silicon (poly-Si), gallium arsenide (GaAs), germanium (Ge) or silicon-germanium (SiGe). The thickness of the semiconductor device layer 128 may range from about 50 nm to about 90 nm, typically about 70 nm but is not so limited. The support substrate 104 is typically Si but may be formed from any suitable semiconductor materials including, but not limited to sapphire, poly-silicon, silicon oxide (SiO₂) or silicon nitride (Si₃N₄). In this regard, an SOI substrate can also be considered as a support substrate 104. The BOX layer 106 is usually an insulating layer. The BOX layer 106 is typically SiO₂ but may be formed from any suitable insulating materials including, but not limited to tetraethylorthosilicate (TEOS), silane (SiH₄), silicon nitride (Si₃N₄) or silicon carbide (SiC). The thickness of the BOX layer 106 may range from about 1 kA to about a few μm but is not so limited.

In FIG. 3A, prior to any deposition, the Si device layer 128 may be thinned down to a range between about 10 nm to about 40 nm, typically about 25 nm thick by oxidation. The oxidation may be a wet oxidation (done in H₂O vapor) or dry oxidation (done in O₂ gas) or any other suitable techniques. The thinning of the Si device layer 128 is an optional step and the purpose of the thinning is so as to maintain the resultant FinFET height, which is a result of a combination of the thickness of the Si device layer 128 and the thickness of the subsequent SiGe layer. To maintain the resultant FinFET height within a desired height, the Si device layer 128 may be thinned so that a thicker SiGe layer may be deposited subsequently, thereby allowing higher Ge content film formation. A thicker SiGe layer and a thinner Si device layer 128 will give rise to a higher Ge content SGNW in the resultant structure.

After the thinning step, a surface clean step may be carried out with RCA and hydrogen fluoride (HF). This surface clean step is carried out because contaminants present on the surface of the Si device layer 128 at the start of processing, or accumulated during processing, have to be removed at specific processing steps in order to obtain high performance and high reliability semiconductor devices, and to prevent contamination of process equipment, especially the high temperature oxidation, diffusion, and deposition tubes or chambers. The RCA clean is the industry standard for removing contaminants from substrates or wafers. The RCA cleaning procedure usually has three major steps used sequentially: Organic Clean (for example removal of insoluble organic contaminants with a 5:1:1 H₂O:H₂O₂:NH₄OH solution), Oxide Strip (for example removal of a thin silicon dioxide layer using a diluted 50:1 dionized-water H₂O:HF solution) and metallic Ion Clean (for example removal metal atomic contaminants using a solution of 6:1:1 H₂O:H₂O₂:HCl). Sulfuric acid (H₂SO₄) mixed with Hydrogen Peroxide (H₂O₂) clean may also be used. Other types of cleaning solutions or steps may also be used.

After the surface clean step; a starting SiGe epitaxial layer 130 with uniform Ge content in the range of about 15% to about 25% may be grown on the Si device layer 128 as shown in FIG. 3B. The SiGe layer 130 may be grown using a cold wall Ultra High Vacuum Chemical Vapor Deposition (UHVCVD) reactor at a temperature from about 500° C. to about 600° C., typically about 580° C. but not so limited, with a combination of SiH₄ and germane (GeH₄) gases. The thickness of the SiGe layer 130 is between about 30 nm to about 60 nm but is not so limited. Alternatively, a plurality of alternate layers of SiGe and Si may also be grown on the Si device layer 128 to form a resultant stacked nanowire structure. In this example, Si will be deposited by SiH₄ gas only. GeH₄ turn-off or turn-on during different film deposition cycles may be used to induce the respective Si, SiGe layers. In addition, different SiGe films may be obtained by varying the GeH₄, SiH₄ flow ratio. Temperature may also be in the range of about 500° C. to about 600° C. for this type of UHVCVD configuration.

An optional Si capping layer (not shown) may also be deposited on the SiGe layer 130. The Si capping layer serves as a sacrificial layer during the gate dielectric or oxide formation, and also during the passivation to SiGe to prevent Ge exposure. The oxidation process will consume the top Si capping layer but not the SiGe layer as the oxide quality on this SiGe surface is typically inferior when compared to that of oxide interfaced with Si.

After the growth of the SiGe epitaxial layer 130 and optional deposition of the Si capping layer, a first Ge condensation process and a cyclic annealing step may be carried out. Ge condensation may be achieved by thermal oxidation of the SiGe layer whereby Si oxidizes faster when compared to Ge, and the Ge atoms are rejected from the SiO₂ layer into the SiGe layer below. The Ge diffusion and accumulation are dependent on the thermal environment and vary with gas flow and temperature. Higher Ge-content SiGe layer can be obtained when subjected to a longer oxidation period.

FIG. 3C shows a resultant structure 136 after the first Ge condensation and the cyclic annealing step. The resultant structure 136 includes an oxidized layer (SiO₂ layer 132) on a resultant SiGe layer 134, with the resultant SiGe layer 134 arranged on the BOX layer 106. The Ge atoms are rejected from the SiO₂ layer 132 into the SiGe layer 134 below. The cyclic annealing step may be carried out at temperatures of about 750° to about 950° but not so limited. The cyclic annealing step is carried out so as to reduce any defects, and also to distribute the Ge evenly across the SiGe layer 134 dynamically.

After the first Ge condensation process, the SiO₂ layer 132 may be etched away using a suitable etchant for example dilute hydrofluoric acid (DHF) (1:200). FIG. 3D shows the resultant SiGe layer 134 on the BOX layer 106 after the etching process, forming a structure termed SiGe on insulator (SGOI) 138. The thickness of the resultant SiGe layer 134 is about 20 nm to 30 nm but is not so limited. The Ge percentage and the resultant SiGe layer 134 thickness are respectively determined by the thickness of the Si device layer 128, the thickness of the starting SiGe layer 130 and the Ge condensation time for example.

Next, a relatively thin liner oxide layer or pad oxide layer (not shown) is deposited on the resultant SiGe layer 134. The purpose of the thin liner oxide layer is to protect the SiGe layer 134 from any subsequent deposited layers (e.g. silicon nitride (SiN) hard mask layer). For example, the liner oxide layer prevents exposure of the resultant SiGe layer 134, where the surface may be oxidized easily and unevenly. Subsequently, a SiN hard mask layer (not shown) is deposited on top of the thin liner oxide layer. Other examples of hard mask include a combination of SiN and SiO₂ stacks. Then a photoresist layer (not shown) is applied or coated onto a top surface of the SiN hard mask layer. The photoresist layer is then patterned to form a fin structure including a fin portion arranged in between two supporting portions by standard photolithography techniques, for example 248 nm krypton fluoride (KrF) lithography. Alternating-Phase-Shift mask (Alt-PSM) may be used to pattern the narrow fin portion which may have a width of about 40 nm to about 200 nm but is not so limited. Subsequently, using the patterned photoresist layer as a mask, portions of the SiN, the liner oxide layer and the SiGe layers 134 not covered by the mask may be etched away by a suitable etching process such as a dry etching process for example reactive-ion-etching (RIE) in Sulfur Hexafluoride (SF₆).

In FIG. 3E, a resultant fin structure 140 comprising of a fin portion 142 arranged in between and connected at each end to a respective supporting portion 144 is formed on the BOX layer 106. The fin portion 142 acts as a bridge linking the respective supporting portions 144. The supporting portions 144 are typically blocks with a wider dimension when compared to the fin portion 142. FIG. 3E shows that the fin portion 142 is arranged in the middle between the two supporting portions 144. Alternatively, the fin portion 142 can also be arranged towards either side of the two supporting portions 144. The fin portion 144 has a width (denoted by “w”) of about 40 nm to about 200 nm, but not so limited. With height (denoted by “h”) typically from about 1 kA to about 2 kA, the ratio of height to width in such fin portion 142 may range from 5:1 to 1:2, but not so limited.

After forming the fin structure 140, the photoresist layer is removed or stripped away by a photoresist stripper (PRS). Photoresist stripping, or simply ‘resist stripping’, is the removal of unwanted photoresist layer. Its objective is to eliminate the photoresist material as quickly as possible, without allowing any surface material under the photoresist to be attacked by the chemicals used. In this regard, any other suitable techniques or processes may also be used in order to provide greater flexibility with respect to forming of the fin structure comprising the fin portion arranged in between two supporting portions on the BOX layer.

The fin structure 140 is then subjected to a second Ge condensation process at a temperature of about 875 degree and for about 10 minutes, but not so limited. In FIG. 3F, the second Ge condensation step resulted in the formation of a SGNW structure 146 including an oxide-encapsulated Ge-rich SGNW channel 148 connected on both sides to lower Ge-content supporting portions 150. The diameter of the resultant SGNW channel 148 is between 7 nm to 13 nm but not so limited.

During this second Ge condensation, a pattern size and shape dependent Ge condensation takes place. The second Ge condensation is a process which converts the fin structure 140 from a homogeneous structure (homostructure) to a heterostructure. In the narrower fin portion 142, the second condensation proceeds 2-dimensionally (almost from all 4 sides) as opposed to 1-dimensionally in the larger supporting portions 144 (only from the top). Ge atoms diffused from the top and side surfaces into the center of the fin portion 142, further enriching the Ge concentration, and simultaneously reducing cross-sectional dimensions of the fin portion 142. This resulted in Ge enrichment within the resultant SGNW channel 148, along with size reduction of the fin portion 142 from a range between about 40 nm to about 200 nm to the resultant SGNW channel 148 diameter of between about 7 nm to about 13 nm. The supporting portions 144 maintained almost the same Ge concentration as obtained by the first Ge condensation.

Subsequently, cyclic annealing is performed before the SiN mask layer may be washed away by phosphoric acid (H₃PO₄ for example). Cyclic annealing before oxide removal is helpful to prevent breakage in the SGNW 148, possibly due to stress relief or redistribution in the SGNW 148. Then the hard mask is being etched away. The thin liner oxide layer and the SiO₂ layer 153 surrounding the SGNW 148 is also etched using dilute hydrofluoric acid (DHF) (1:200) to release the SGNW 148. Any other suitable etchant can also be used to release the SGNW 120. The dimension of each SGNW 148 is about 7 nm to 13 nm but not so limited. The diameter of each SGNW 148 may be determined by the initial layer deposition and oxidation cycles. The result is a SGNW channel 148 supported on both ends by the respective supporting portions 150 after the second Ge condensation on the BOX layer 106 as shown in FIG. 3F. The ratio of the width of the respective supporting portions 150 and the diameter of the SGNW 148 may be greater than a range between about 2 to about 20, typically about 10.

Subsequently, the nanowire release may be followed by a surface passivation step where the surface of the SGNW 148 is passivated with about 2 nm but not so limited of epitaxial Si layer (not shown). The passivation layer serves as a sacrificial layer. The oxidation process consumes the passivation layer before the oxidants reach to the channel surface, which is the SGNW 148. This allows for the oxide and channel interface to be maintained within the Si passivation layer instead of into the SGNW 148. This is followed by an oxide growth (not shown) with a resultant oxide thickness of about 4 nm to 8 nm but not so limited forming the gate dielectric. The oxide may be grown by a dry oxidation process at a temperature of between about 800° to about 900° or by a CVD process. The gate dielectric may be any suitable dielectric for example SiO₂, SiNₓ, MgO or Sc₂O₃.

Next in FIG. 3G, a conductive layer (not shown) of about 1300 Angstrom thick is deposited over the oxide layer by low power physical vapor deposition (PVD). The conductive layer may be silicon, poly-silicon, amorphous silicon, metals such as tantalum nitride (TaN), titanium nitride (TiN), hafnium nitride (HfN), aluminum (Al) and tungsten (W) but not so limited. This is followed by patterning and etching of the conductive layer to form the gate electrode 152. The gate length is about 75 nm but not so limited. The gate electrode 152 can be deposited as intrinsically undoped, having different doping based on the doping methods or as metal gates.

Subsequently in FIG. 3H, the supporting regions 144 of the fin structure 140 may be implanted with a p-type dopant or a n-type dopant to form the respective source 112 and drain regions 116 and the gate electrode 152 may be implanted with a dopant of opposite conductivity to that of the supporting regions 144 of the fin structure 140. To realize SGNW PMOSFET, p-type dopants for example BF₂ with a dose of about 4×10¹⁵ cm⁻² at about 35 keV may be implanted into the supporting regions 144 to form the respective source region 112 and the drain region 116. Any other suitable p-type dopant such as aluminum, gallium and indium may also be used. An N-type dopant for example Arsenic (As) with a dose of about 4×10¹⁵ cm⁻² at about 30 keV may be implanted into the gate electrode 152. The gate 152 and source 112 or drain 116 may be implanted at the same time. Any other suitable n-type dopants such as phosphorous (P), antimony (Sb), bismuth (Bi) may also be used. Incidentally, the nanowires are without any intentional doping and the combination of gate electrode 152 types and dopants adopted for the source 112 or drain 116 implant define whether the transistor will be a p-channel MOSFET (PMOSFET) or an n-channel MOSFET (NMOSFET).

After the respective dopant implants, a source 112, drain 116 and gate 152 activation anneal step at a temperature of approximately 875° for 15 minutes may be carried out to ensure uniform diffusion of dopants in the source 112, drain 116 and gate 152 regions. The process of forming the SGNW MOSFET 102 may be completed by the standard metal contact formation and sintering steps.

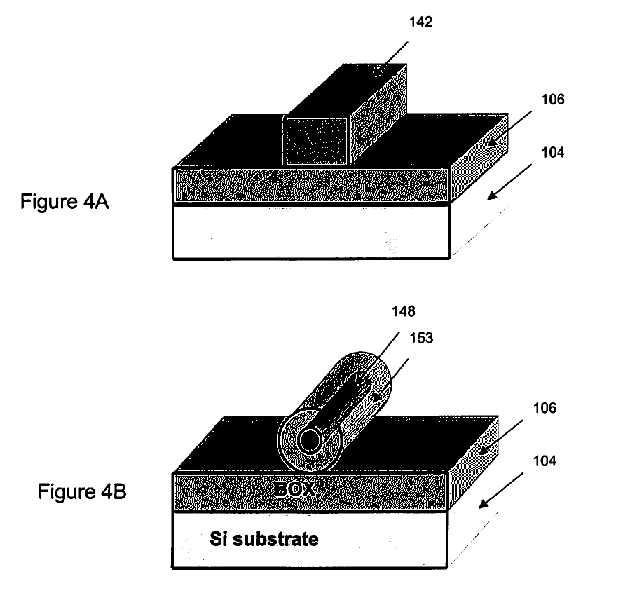

FIG. 4A show a cross-sectional view along plane AA′ of the SGNW transistor in FIG. 3E after fin patterning and before second Ge condensation in accordance with an embodiment of the present invention. FIG. 4A shows a SiGe fin portion 142 disposed on the BOX layer 106. The BOX layer 106 is further arranged on the support substrate 104.

FIG. 4B show a cross-sectional view along plane AA′ of the SGNW transistor in FIG. 3E after fin patterning and after second Ge condensation in accordance with an embodiment of the present invention. In FIG. 4B, the SiGe fin portion 142 is oxidized resulting in a SGNW 148 surrounded by a layer of SiO₂ layer 153. The SGNW 148 surrounded by the SiO₂ layer 153 is disposed on the BOX layer 106 and the BOX layer 106 is further arranged on the support substrate 104.

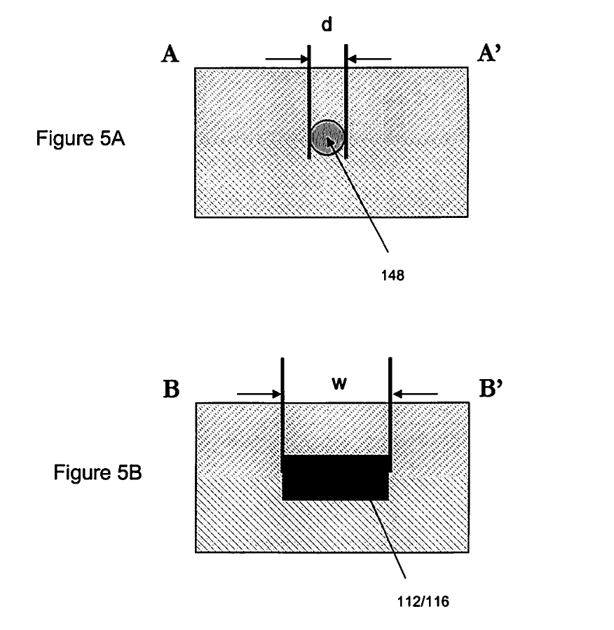

FIG. 5A and FIG. 5B show cross-sectional views along planes AA′ and BB′ of the SGNW transistor 102 in FIG. 3F in accordance with an embodiment of the invention. FIG. 5A shows that the Ge concentration of the SGNW 148 is about 70% and the diameter (denoted by “d”) of the SGNW 148 may be a range between about 7 nm to about 13 nm. FIG. 5B shows the Ge concentration of the respective SiGe source 112 or drain region 116 is about 30% and the width (denoted by “w”) of the respective SiGe source 112 or drain region 116 is about 1 μm but not so limited. The width of the SiGe source 112 or drain region 116 is substantially larger than the diameter of the SGNW 148 so that the oxidation is effected mainly in the fin portion 142.

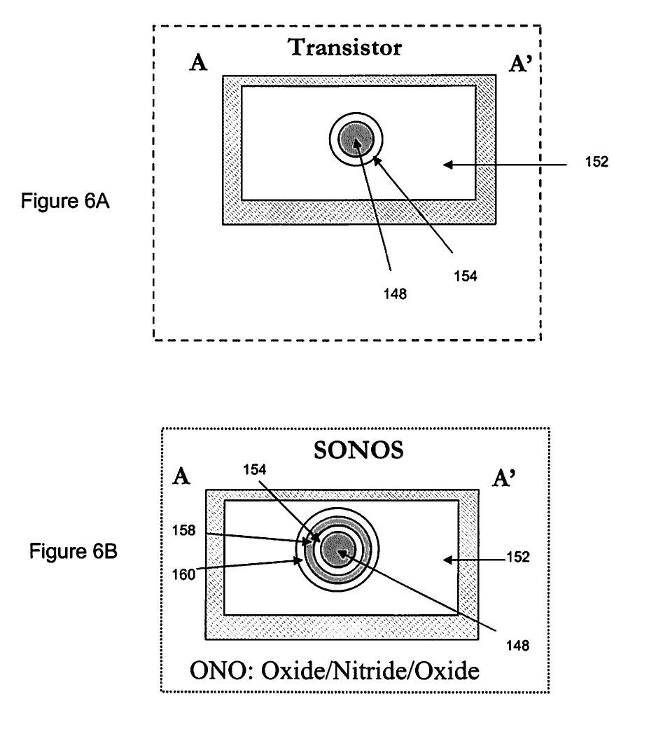

FIG. 6A and FIG. 6B show respective cross-sectional views along plane AA′ of the SGNW transistor in FIG. 3G with the resultant structure being a MOSFET or a SONOS memory device in accordance with an embodiment of the invention. FIG. 6A shows a cross-sectional view with the resultant structure of a MOSFET. To form the MOSFET, the SGNW channel 148 is surrounded by a tunneling oxide layer 154 and is subsequently surrounded by a gate region 152. The tunneling oxide layer 154 is a dielectric layer and the dielectric layer 154 may be SiO₂, HfO₂, SiNₓ, MgO or Sc₂O₃ but not so limited. The gate region or gate layer 152 may be tantalum nitride (TaN), titanium nitride (TiN), typically poly-Si, but not so limited. The thickness of the gate region 152 is about 1 kA to about 2 kA and the thickness of the dielectric layer 154 is about 45 A.

FIG. 6B shows a cross-sectional view with the resultant structure of a SONOS memory device. To form the SONOS, the SGNW 148 is surrounded by a tunneling oxide layer 154 and a charge trapping structure 158 is positioned over the tunneling oxide layer 154. A blocking oxide layer 160 is further positioned over the charge trapping structure 158 and the blocking oxide layer 160 is surrounded by a gate region 152. For the SONOS, the tunneling oxide layer 154 surrounding the SGNW channel 148 is a dielectric layer and the blocking oxide layer 160 surrounding the charge trapping structure 158 is also a dielectric layer. The dielectric layer is typically SiO₂ but not so limited. The charge trapping structure 158 may include any one or more of a group of high dielectric materials, for example silicon nitride (Si₃N₄), hafnium dioxide (HfO₂), aluminum oxide (Al₂O₃) but not so limited. The tunneling oxide layer 154 is typically about 45 A thick, the charge trapping structure 158 is typically about 45 A thick and the blocking oxide layer 160 is typically about 80 A thick, but not so limited. The SGNW channel 148 may be used in all non-volatile applications.

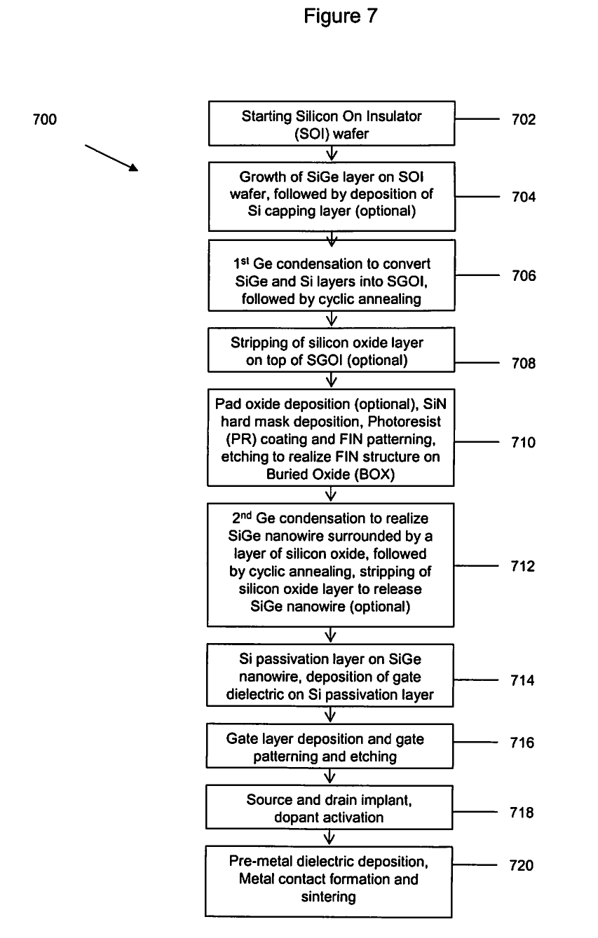

FIG. 7 shows a flow chart of a method of forming a SGNW transistor in accordance with an embodiment of the invention. The method 700 begins at 702 with a starting SOI substrate 126 comprising a Si device layer 128 separated vertically from a support substrate 104 by a BOX layer 106. Next, in 704 a layer of SiGe 130 is grown on the Si device layer 128 of the SOI substrate 126. An optional Si capping layer may be deposited on the SiGe layer 130. In 706, a first Ge condensation step is carried out to convert the SiGe layer 130 on the Si device layer 128 into a SiO₂ layer 132 on a SiGe layer 134, forming a SGOI 138. This is followed by cyclic annealing. Next in 708, the SiO₂ layer 132 is stripped away using a suitable etchant. In step 710, an optional pad oxide layer is deposited on the SiGe layer 134. This is followed by a SiN hard mask deposition on the pad oxide layer. Then, a photoresist layer is coated onto the SiN hard mask layer. The photoresist layer is then patterned to form a fin structure including a fin portion arranged in between two supporting portions by standard photolithography techniques. Using the fin pattern photoresist layer as a mask, portions of the SiN, pad oxide layer and SiGe layer 134 not covered by the mask are etched away to realize a fin structure 140 comprising of a fin portion 142 arranged in between two supporting portions 144 on the BOX layer 106. In 712, the fin structure 140 is further subjected to a second Ge condensation process to achieve a nanowire structure 146 with a SGNW 148 being surrounded by a layer of oxide 153. Subsequently, the nanowire structure 146 is subject to an annealing step to repair the crystal defects. Next, the oxide layer 150 surrounding the SiGe supporting portions 144 and the oxide layer 153 surrounding the SGNW 148 are etched. Removal of the SiO₂ layer 153 surrounding the SiGe core 148 releases the SGNW 148 thereby forming the resultant SiGe nanowire structure. In 714, a Si passivation layer is grown on the SGNW 148, followed by deposition of a gate dielectric layer on the Si passivation layer. In 716, a conductive layer is deposited, followed by gate patterning and etching to form the gate electrode 152. In 718, the supporting portions 144 are doped to form the source 112 and drain regions 116 of the respective SGNW MOSFET 102. The gate electrode 152 may also be doped with a different dopant from that of the resultant source 112 and drain 116 regions. This is followed by an annealing step to ensure uniform diffusion of dopants in the source 112, gate 152 and drain 116 regions. In 720, the method of forming a SGNW MOSFET 102 may be completed with the standard pre-metal dielectric deposition, metal contact formation and sintering steps.

### Results

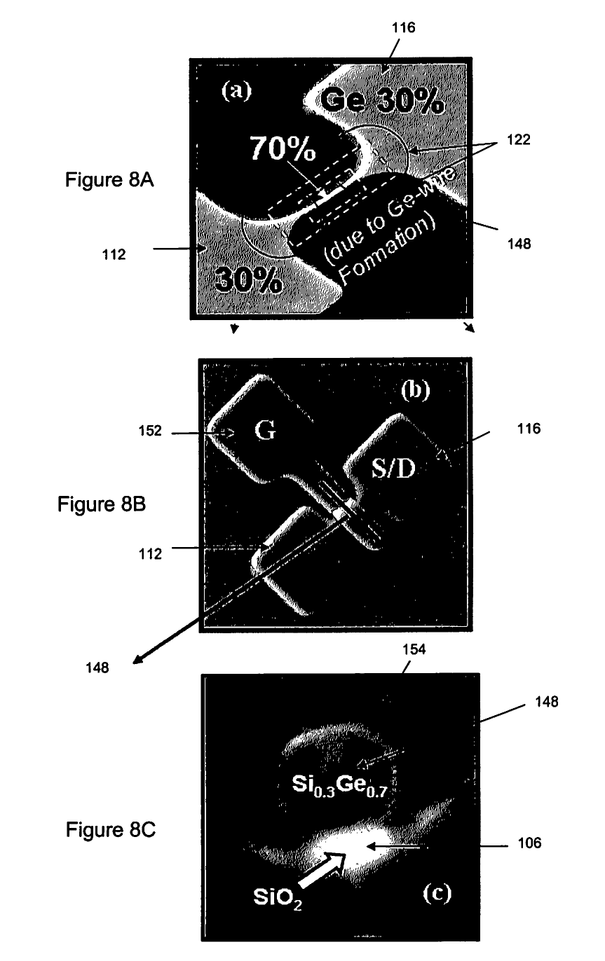

FIG. 8A shows a SEM image of a SGNW structure taken after a second Ge condensation process in accordance with an embodiment of the invention. FIG. 8A shows a SGNW channel 148 arranged between respective source 112 and drain 116 extension pads. The Ge concentration in the SGNW channel region 148 is about 70% and the Ge concentration in the respective source 112 or drain 116 extension pads is about 30%, thereby forming a heterojunction 122. In FIG. 8A, the gate edge is sitting on the wider curved extensions of the nanowires (corner rounding effect in lithography). Being wide, the curved extension has a much lower Ge concentration compared to the nanowire channel 148. The heterojunction 122 is formed under the gate region 152, thereby fulfilling the requirement for the formation of a heterojunction MOSFET. Since pattern-dependent Ge condensation is employed, the heterojunction 122 will not be abrupt. A non-abrupt heterojunction can result in enhanced carrier injection velocity and further help to reduce the energy carrier spike at the source heterojunction 122. In pattern dependent Ge condensation, pattern abruptness (radii of curvature of the curved extensions) can be used to tune the abruptness of the heterojunction 122, so as to obtain an optimum heterojunction abruptness in accordance with design considerations.

FIG. 8B shows a SEM image of a SGNW structure after gate pattern transfer in accordance with an embodiment of the invention. FIG. 8B shows the respective source 112 and drain 116 regions with the SGNW 148 arranged there between. The gate region 152 overlaps the SGNW 148. Good alignment of the gate pattern helps to prevent nanowire breakage after gate etching.

FIG. 8C shows a cross-sectional HRTEM image of a SGNW in accordance with an embodiment of the invention. The SGNW channel 148 is substantially round with a diameter of a range between about 7 nm to about 13 nm. The SGNW 148 has a Ge concentration of about 70%. The SGNW 148 is covered with an HfO₂ dielectric layer 154 on the top and at the sides, and is further supported on the bottom by residual buried SiO₂ 106, forming an omega-gated channel. Using a fast Fourier transform-based method of HRTEM strain analysis, the SGNW 148 is found to be compressively strained (about −0.6%).

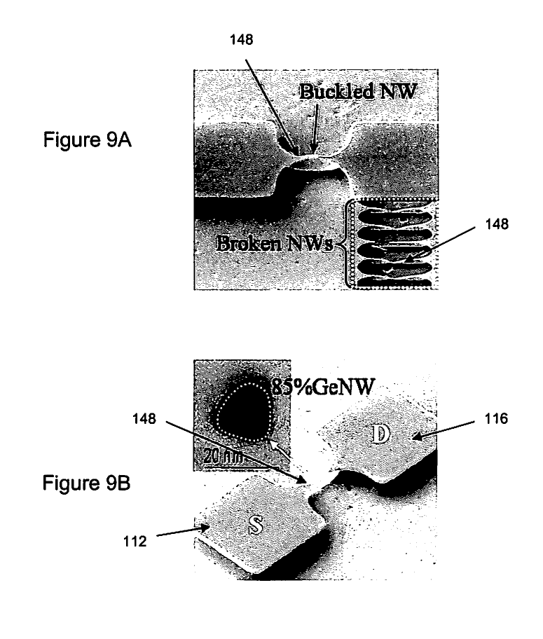

FIG. 9A shows a SEM image of a SGNW structure after nanowire release in accordance with an embodiment of the invention. During Ge condensation, the SGNW 148 developed a high compressive stress. The released SGNW 148 with Ge concentration of about 85% were found to be more fragile than Si nanowires of the same dimensions and tend to buckle or break upon oxide removal. Cyclic annealing before oxide removal may be helpful in avoiding breakage due to stress relief or redistribution in the nanowires. In FIG. 9A, buckled nanowires or buckling on the nanowires 148 can be seen. Ge-rich nanowires can be fragile. The inset shows a plurality of broken nanowires 148.

FIG. 9B shows a SEM image of a SGNW structure after nanowire release taken with about 45 degree rotation in accordance with an embodiment of the invention. After implementing stress release temperature cycles, released nanowires remain substantially straight. The substantially straight SGNW 148 is seen bridging the source 112 or drain 116 pads after oxide strip. The inset shows a cross-sectional TEM of the fabricated SGNW 148 with a Ge concentration of about 85% and a diameter of about 20 nm.

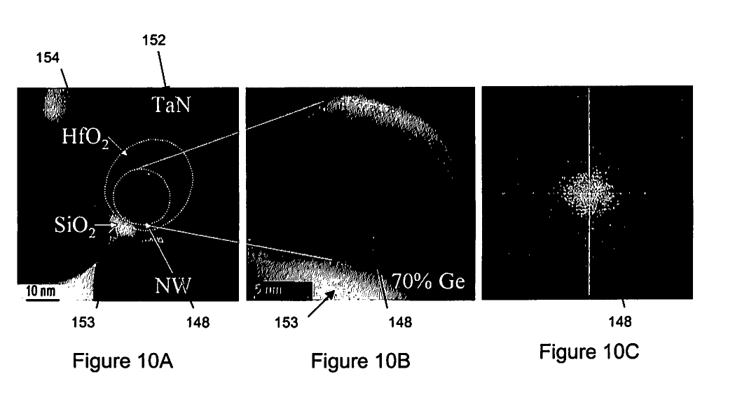

FIG. 10A shows a TEM image of a SGNW GAA FET with HfO₂/TaN gate in accordance with an embodiment of the invention. The HfO₂ 154 and TaN gate 152 has almost surrounded the SGNW channel 148. The HfO₂ 154 is thicker on the top than the sidewalls due to the non-conformal nature of physical vapor deposition (PVD) process. The whitish amorphous layer below the nanowire 148 is SiO₂ 153 that was not completely removed in the release process

FIG. 10B shows a magnified image of a near-circular SGNW in accordance with an embodiment of the invention. The bright layer at the periphery is a result of Si passivation layer. Similarly, the whitish amorphous layer below the nanowire 148 is a SiO₂ layer 153 that may not completely removed in the release process. A HRTEM based technique was used to estimate the strain in the nanowires. Using the Si (111) lattice spacing from the substrate as a reference, the SGNW 148 were found to be under lateral compressive strain of about −0.6%.

FIG. 10C shows a reciprocal space diffractogram showing a lattice structure inside the SGNW 148 in accordance with an embodiment of the invention. The calculated strain in the nanowire 148 is about −0.6% compressive. The presence of sharp and distinct spots in the diffractogram implies the absence of defects and good crystallinity in the SGNW 148.

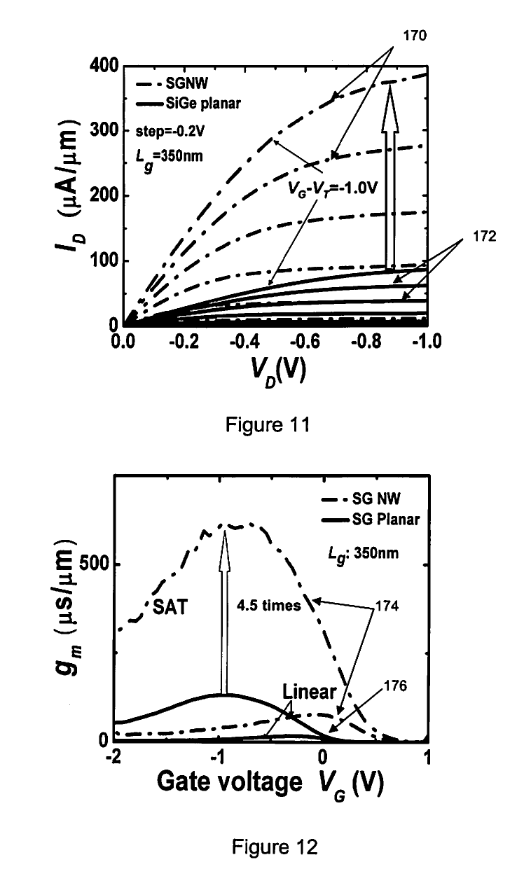

The electrical performance of the fabricated heterojunction SGNW p-channel metal-oxide-semiconductor field effect transistor (PMOSFET) is presented in FIG. 11 and FIG. 12. FIG. 11 shows a normalized I_{D} vs V_{D} characteristics plot of a SGNW PMOSFET and a Si_{0.7}Ge_{0.3} homo planar device with gate length (Lg) of approximately 350 nm in accordance with an embodiment of the invention. The normalized I_{D} vs V_{D} characteristics plot of the SGNW PMOSFET are represented by curves 170 and the normalized I_{D} vs V_{D} characteristics plot of the Si_{0.7}Ge_{0.3} homo planar device are represented by curves 172. The drain current of SGNW 148 may be normalized by its perimeter (assuming a GAA channel with surface inversion) while that of the planar device current may be normalized by channel width. The drive current of SGNW 148 may be about 4.5 times larger than planar devices. High drive current of SGNW 148 implies large effective mobility for these strained Ge rich nanowire MOSFETs 102 with lateral heterojunction structure.

FIG. 12 shows a transconductance (g_{M}) vs gate voltage (V_{G}) characteristic plot of a SGNW PMOSFET and a Si_{0.7}Ge_{0.3} homo planar device with Lg of approximately 350 nm in accordance with an embodiment of the invention. The transconductance (g_{M}) vs gate voltage (V_{G}) characteristic plot of the SGNW PMOSFET is represented by curve 174 and the transconductance (g_{M}) vs gate voltage (V_{G}) characteristic plot of the Si_{0.7}Ge_{0.3} homo planar device is represented by curve 176. A similar trend to that of the drive current was found for the gₘ value. The peak gₘ value in saturation region as well in linear region for SGNW devices is about 4.5 times larger than for planar devices. Saturation gₘ does not drop too rapidly after the peak, which indicates that on-state channel resistances dominate compared to the parasitic series resistance at lower gate overdrive voltages.

The enhancement in normalized current and gₘ can mainly be attributed to the following factors. Firstly, owing to the novel hetero junction structure of SGNW 148, hole velocity is enhanced due to an excess kinetic energy which results from the source to channel valence band offset ΔE_{V}. Secondly, Ge concentration of SGNW channel 148 is 70%, leading to larger hole mobility than the planar channel with lower Ge content. Thirdly, lateral compressive strain (about −0.6%) in the SGNW channel 148 further increases the hole mobility. Fourthly, the nanowire 148 benefits from having a smaller equivalent oxide thickness (EOT) at the sidewalls due to the non-conformal nature of PVD dielectric deposition. However, EOT is thicker at the bottom due to residual buried SiO₂ oxide 106. Lastly, the SGNW transistor 102 has a smaller access resistance due to the funnel-shaped extension regions.

For the SGNW 148 with the heterojunction 122 structure, higher hole injection is expected due to the valence band offset from the source region 112 towards the channel region 148. In order to evaluate this aspect, both SGNW 148 and planar devices are characterized at different temperatures and a backscattering coefficient is extracted using a temperature-dependent analytical model:

$$backscattering coefficient {r}_{sat} = \frac{1}{1 + \frac{{λ}_{0}}{{l}_{0}}} , \\ with \frac{{λ}_{0}}{{l}_{0}} = \frac{4}{0.5 - ( α + \frac{η}{{V}_{G} - {V}_{T , sat}} )} - 2 , \\ where α = \frac{Δ {I}_{Dsat}}{{I}_{Dsat} Δ T} , and η = \frac{Δ {V}_{T}}{Δ T}$$

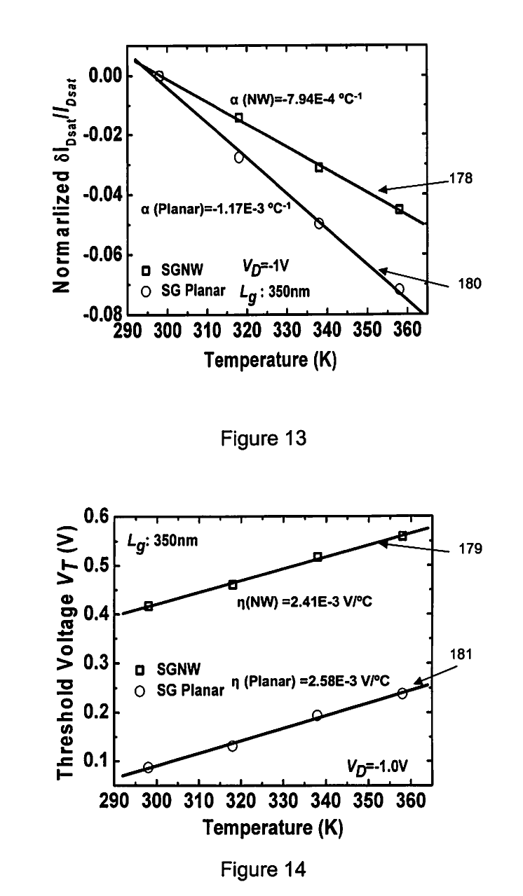

FIG. 13 shows a drive current (I_{Dsat}) vs temperature characteristic plot of a SGNW PMOSFET and a Si_{0.7}Ge_{0.3} homo planar device with Lg of approximately 350 nm in accordance with an embodiment of the invention. The drive current (I_{Dsat}) vs temperature characteristic plot of the SGNW PMOSFET is represented by curve 178 and the drive current (I_{Dsat}) vs temperature characteristic plot of the Si_{0.7}Ge_{0.3} homo planar device is represented by curve 180. The values α of SGNW 148 is obtained from the temperature gradient of I_{Dsat}. As shown in FIG. 13, a of SGNW 148 is about 32% smaller than planar devices. At V_{G}−V_{T,sat}=−2 V, the calculated values of the backscattering coefficient ‘rₛₐₜ’ for nanowire hetero and planar devices are 0.377 and 0.446 respectively. A reduction of 19% compared to planar devices confirms an increase in ballistic efficiency in these hetero-junction SGNW devices.

FIG. 14 shows a threshold voltage (V_{T}) vs temperature characteristics plot of a SGNW PMOSFET 102 and a Si_{0.7}Ge_{0.3} homo planar device with Lg of approximately 350 nm in accordance with an embodiment of the invention. The threshold voltage (V_{T}) vs temperature characteristics plot of a SGNW PMOSFET 102 is represented by curve 179 and the threshold voltage (V_{T}) vs temperature characteristics plot of the Si_{0.7}Ge_{0.3} homo planar device is represented by curve 181. FIG. 14 shows a constant offset of V_{T} vs temperature between the two devices. This may explain the bandgap modification by different Ge content.

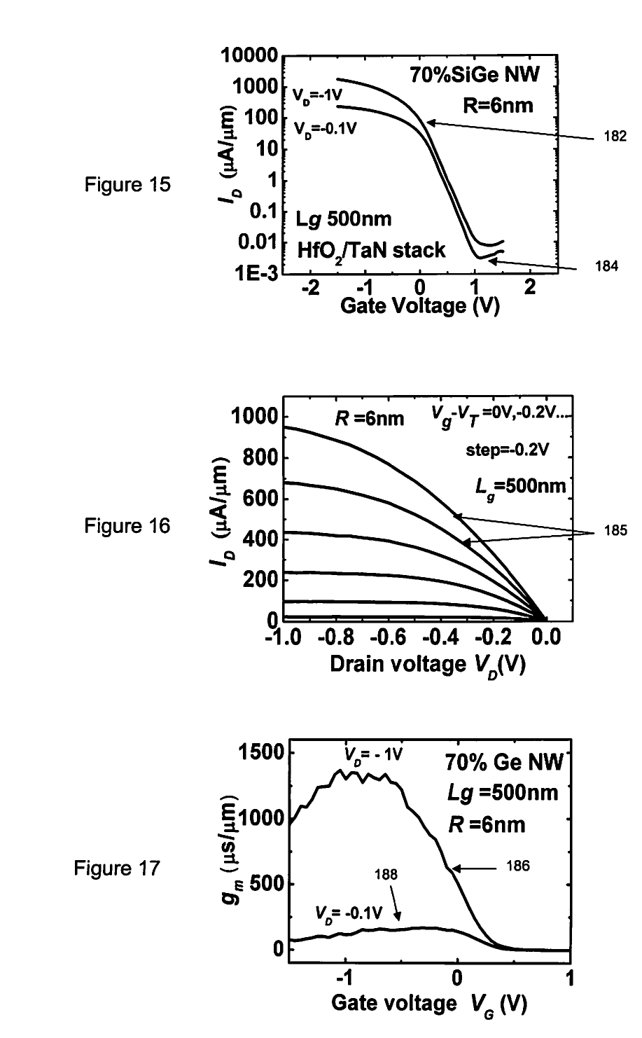

FIG. 15 shows a I_{D} vs V_{G} characteristics plot of a SGNW PMOSFET 102 with Lg of 500 nm in accordance with an embodiment of the invention. The I_{D} vs V_{G} characteristics plot of a SGNW PMOSFET with V_{D}=−1 V is represented by curve 182 and the I_{D} vs V_{G} characteristics plot of a SGNW PMOSFET with V_{D}=−0.1 V is represented by curve 184. The SGNW PMOSFET 102 is formed with an HfO₂/TaN gate, has a Ge concentration of about 70% and a radius of about 6 nm. I_{D} is normalized by wire diameter and V_{T} is about 0.2V. A subthreshold swing (as obtained from the gradient of the plot) of about 200 mV/dec is obtained. This can possibly be attributed to interface states which could have been caused by Ge diffusion to the gate dielectric interface during thermal processes after Si passivation.

FIG. 16 shows a I_{D} vs V_{D} characteristics plot of a SGNW PMOSFET 102 with Lg of 500 nm in accordance with an embodiment of the invention. The I_{D} vs V_{D} characteristics plot of a SGNW PMOSFET 102 with Lg of 500 nm is represented by curve 185. The SGNW PMOSFET 102 is formed with an HfO₂/TaN gate, has a Ge concentration of about 70% and a radius of about 6 nm. At V_{G}−V_{T}=−1.2V, excellent I_{D} performance of about 970 μA/μm was obtained. This is exceptionally high for p-channel devices of similar gate lengths.

FIG. 17 shows a g_{M} vs V_{G} characteristics plot of a SGNW PMOSFET 102 with Lg of 500 nm in accordance with an embodiment of the invention. The g_{M} vs V_{G} characteristics plot of a SGNW PMOSFET with V_{D}=−1V is represented by curve 186 and the g_{M} vs V_{G} characteristics plot of a SGNW PMOSFET with V_{D}=−0.1V is represented by curve 188. The SGNW PMOSFET 102 is formed with an HfO₂/TaN gate, has a Ge concentration of about 70% and a radius of about 6 nm and the V_{T} is about 0.2. The saturation gₘ peak is located at a large gate overdrive. This implies a lower electric field in the SGNW channel 148 due to the GAA structure.

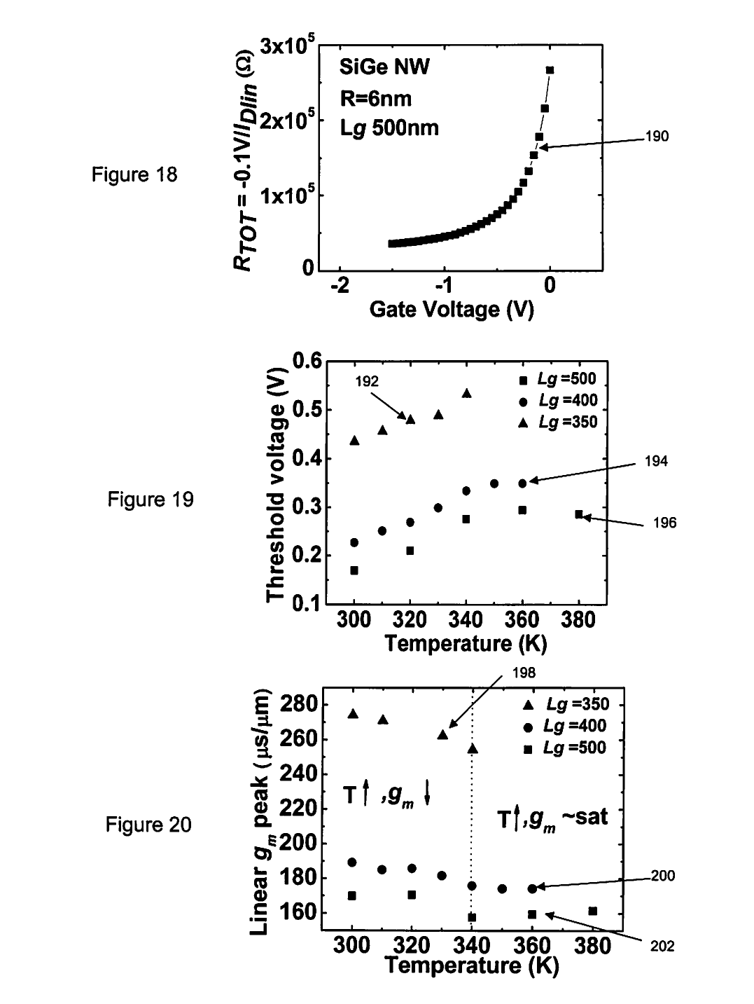

FIG. 18 shows a resistance vs V_{G} characteristics plot of a SGNW PMOSFET 102 at strong inversion with low V_{D} in accordance with an embodiment of the invention. The resistance vs V_{G} characteristics plot of a SGNW PMOSFET 102 at strong inversion with low V_{D} is represented by curve 190. The source or drain series resistance is around 35 kg or 420Ω-μm, which is relatively low.

A study on the impact of temperature on device parameters is also carried out to find the degradation of SGNW PMOSFET 102 for different gate lengths (L_{g}) or about 350 nm, 400 nm and 500 nm respectively. FIG. 19 shows a V_{T} vs temperature characteristics plot of SGNW PMOSFET 102 with respective gate lengths of 350 nm, 400 nm and 500 nm in accordance with an embodiment of the invention. As the temperature increases, threshold voltage shifted positively

FIG. 20 shows a linear g_{M} peak vs temperature characteristics plot of SGNW PMOSFET 102 with respective gate lengths of 350 nm, 400 nm and 500 nm in accordance with an embodiment of the invention. The linear g_{M} peak vs temperature characteristics plot of SGNW with respective gate lengths of 350 nm, 400 nm and 500 nm are represented by curves 192, 194 and 196 respectively. At temperatures below 340 k, gₘ decreases as the temperature increases. When the temperature exceeded 340K, varying the temperature did not have much effect on gₘ. This implies that the degradation of mobility saturated when the temperature exceeded 340K.

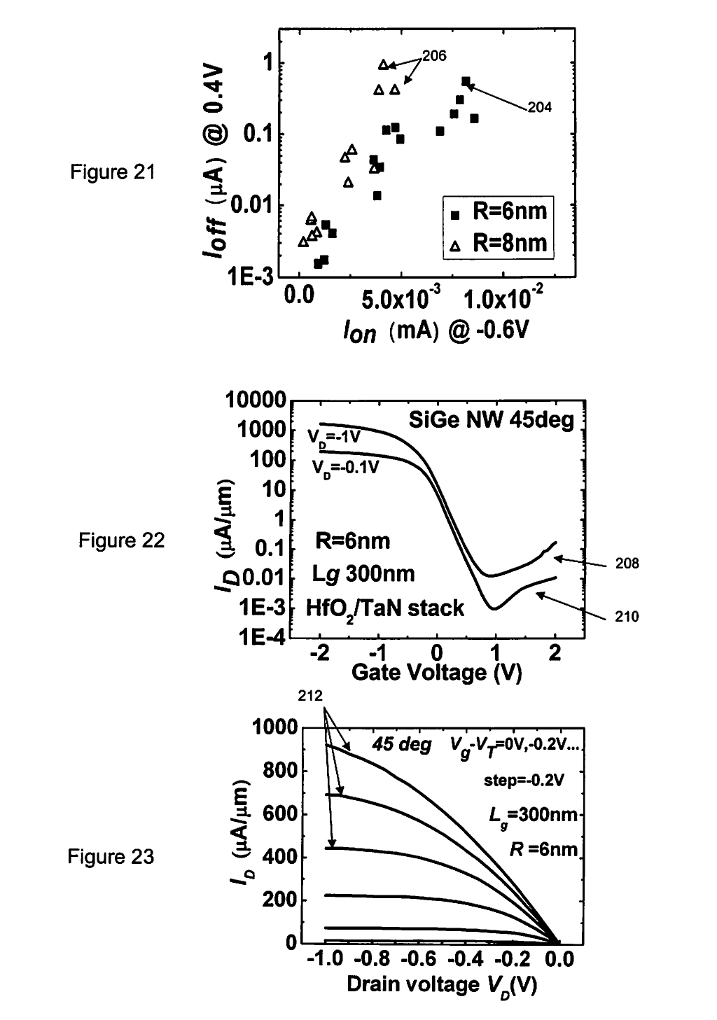

FIG. 21 shows a I_{ON} vs I_{OFF} characteristics plot of SGNW PMOSFET 102 with respective radii of 6 nm and 8 nm in accordance with an embodiment of the invention. The I_{ON} vs I_{OFF} characteristics plot of SGNW MOSFET 102 with radii of 6 nm and 8 nm are represented by curves 204 and 206 respectively. SGNWs 148 with smaller nominal radii show enhanced performance. Smaller NW devices (or SGNWs with smaller nominal radii) are likely to have higher Ge content. This causes mobility enhancement due to Ge's intrinsically higher mobility than Si, as well as drastic reduction in alloy scattering effects, which would otherwise degrade mobility in SiGe. This could be responsible for the large enhancement in Iₒₙ−I_{off} performance.

FIG. 22 shows a I_{D} vs V_{G} characteristics plot of a SGNW PMOSFET 102 with <100> channel direction in accordance with an embodiment of the invention. The I_{D} vs V_{G} characteristics plot of a SGNW PMOSFET 102 with <100> channel direction and with V_{D}=−1V is represented by curve 208 and the I_{D} vs V_{G} characteristics plot of a SGNW PMOSFET 102 with <100> channel direction and with V_{D}=−0.1V is represented by curve 210. The SGNW PMOSFET was formed with a HfO₂/TaN gate, has a Ge concentration of about 70% and a radius of about 6 nm. The gate length L_{g} is about 300 nm. Plot—is for a V_{D} value of −1V and plot—is for a VD value of −0.1 V.

FIG. 23 shows a I_{D} vs V_{D} characteristics plot of a SGNW PMOSFET 102 with <100> channel direction in accordance with an embodiment of the invention. The I_{D} vs V_{D} characteristics plot of a SGNW PMOSFET 102 with <100> channel direction is represented by curve 212. The SGNW PMOSFET 102 is formed with a HfO₂/TaN gate, has a Ge concentration of about 70% and a radius of about 6 nm. The gate length L_{g} is about 300 nm. This figure shows well behaved transistor characteristics.

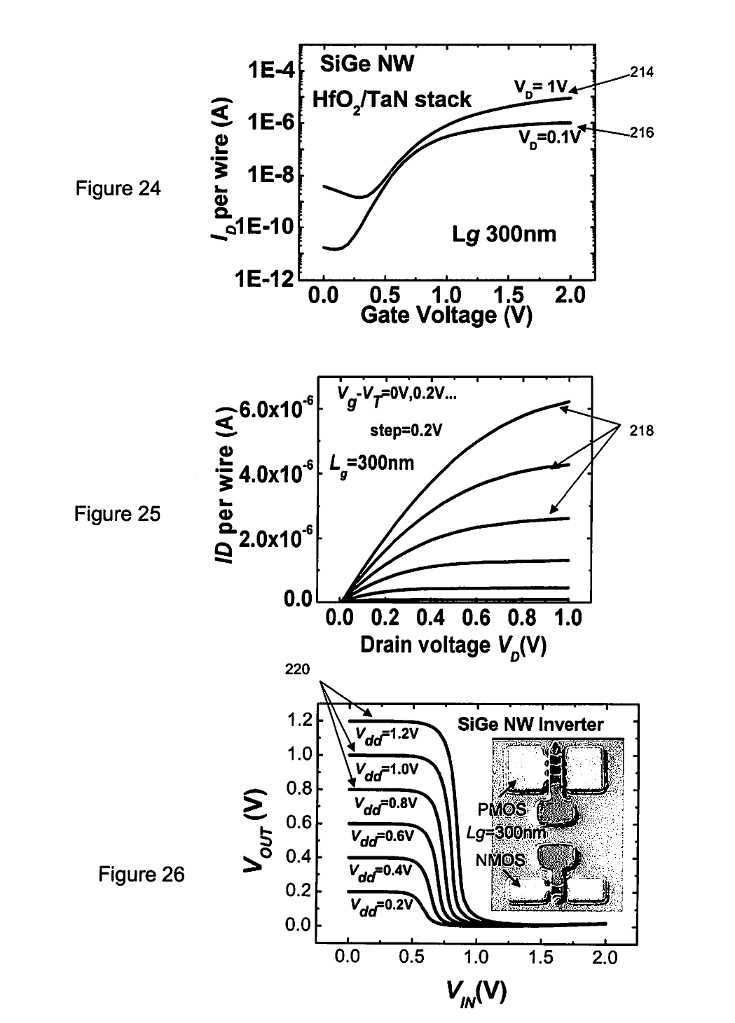

FIG. 24 shows a I_{D} vs V_{G} characteristics plot of a unpassivated SGNW n-channel metal-oxide-semiconductor field effect transistor (NMOSFET) in accordance with an embodiment of the invention. The I_{D} vs V_{G} characteristics plot of a unpassivated SGNW NMOSFET with V_{D}=1V is represented by curve 214 and the I_{D} vs V_{G} characteristics plot of a unpassivated SGNW NMOSFET with V_{D}=0.1V is represented by curve 216. Without Si passivation, gate leakage becomes significant despite lower Ge content in SGNW 148.

FIG. 25 shows a I_{D} vs V_{D} characteristics plot of an unpassivated SGNW NMOSFET in accordance with an embodiment of the invention. The I_{D} vs V_{D} characteristics plots of an unpassivated SGNW NMOSFET are represented by curve 218.

FIG. 26 shows a V_{OUT} vs V_{IN} characteristics plot of a CMOS inverter incorporating a SGNW structure in accordance with an embodiment of the invention. The V_{OUT} vs V_{IN} characteristics plot of a CMOS inverter incorporating a SGNW structure at different V_{DD} are represented by curve 220. The inverter characteristics using 30% Ge SGNW NMOSFET and PMOSFET are shown in FIG. 26. The transition is sharp but asymmetric due to high NMOSFET V_{T} caused by TaN work function. The inversion can be achieved down to about 0.2V V_{DD}, indicating the suitability of low voltage operation of these devices.

While embodiments of the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1-42. (canceled)

43. A silicon-germanium nanowire structure arranged on a support substrate, comprising:
at least one germanium-containing supporting portion arranged on the support substrate;
at least one germanium-containing nanowire disposed above the support substrate and arranged adjacent the at least one germanium-containing supporting portion;
wherein germanium concentration of the at least one germanium-containing nanowire is higher than that of the at least one germanium-containing supporting portion; and
wherein a heterojunction is formed at an interface between the at least one germanium-containing nanowire and the at least one germanium-containing supporting portion.

44. The silicon-germanium nanowire structure of claim 43, wherein the ratio of the width of the at least one germanium-containing supporting portion and the diameter of the at least one germanium-containing nanowire is greater than 2.

45. The silicon-germanium nanowire structure of claim 43, further comprising:
an insulating layer arranged between the support substrate and the at least one germanium-containing supporting portion.

46. A transistor comprising the silicon-germanium nanowire structure arranged on a support substrate as defined in claim 43, the transistor further comprising:
a tunneling layer around the at least one germanium-containing nanowire; and
a gate region positioned over the tunneling layer.

47. The transistor of claim 46, further comprising a charge trapping structure surrounding the tunneling layer.

48. The transistor of claim 47, further comprising a blocking layer disposed between the charge trapping structure and the gate region.

49. The transistor of claim 46, wherein the tunneling layer comprises a dielectric material.

50. The transistor of claim 48, wherein the blocking layer comprises a dielectric material.

51. The transistor of claim 49, wherein the dielectric layer comprises any one or more of a group of dielectric materials of silicon oxide, silicon nitride, magnesium oxide, scandium oxide, hafnium dioxide.

52. The transistor of claim 47, wherein the charge trapping structure comprises any one or more of a group of high dielectric materials of silicon nitride, hafnium dioxide and aluminum oxide.

53. The transistor of claim 46, wherein the at least one germanium-containing supporting portion is doped with either a p-type dopant or an n-type dopant.

54. The transistor of claim 53, wherein the p-type dopant is one or more elements selected from the group consisting of boron, aluminum, gallium and indium.

55. The transistor of claim 53, wherein the n-type dopant is one or more elements selected from the group consisting of phosphorus and arsenic.

56. The transistor of claim 53, wherein the gate region may be doped or undoped.

57. The transistor of claim 56, wherein the gate region is doped with dopants of opposite conductivity to that of the at least one germanium-containing supporting portion.

58. A method of forming a silicon-germanium nanowire structure arranged on a support substrate, the method comprising:
forming at least one germanium-containing supporting portion on the support substrate;
forming at least one germanium-containing nanowire above the support substrate and adjacent the at least one germanium-containing supporting portion;
forming a heterojunction at an interface between the at least one germanium-containing nanowire and the at least one germanium-containing supporting portion; and
wherein germanium concentration of the at least one germanium-containing nanowire is higher than that of the at least one germanium-containing supporting portion.

59. The method of claim 58, wherein the ratio of the width of the at least one germanium-containing supporting portion and the diameter of the at least one germanium-containing nanowire is greater than 2.

60. The method of claim 58, further comprising:
forming an insulating layer between the support substrate and the at least one germanium-containing supporting portion.

61. The method of claim 58, wherein forming the at least one germanium-containing supporting portion on the support substrate comprises:
depositing a semiconductor device layer on the support substrate;
depositing a starting germanium-containing layer on the semiconductor device layer; and
oxidizing the starting germanium-containing layer and the semiconductor device layer to form a first oxide layer and a resultant germanium-containing layer to form the at least one germanium-containing supporting portion on the support substrate.

62. The method of claim 61, wherein forming the at least one germanium-containing supporting portion on the support substrate further comprises:
removing the first oxide layer by an etching process.
